(19) United States
(12) Patent Application Publication
(10) Pub. No.: US 2002/0187624 A1
(43) Pub. Date: Dec. 12, 2002

(54) Method for forming metal line of semiconductor device

(76) Inventor: Woo Sig Min, Kyonggi-do (KR)

Correspondence Address: BIRCH STEWART KOLASCH & BIRCH, PO BOX 747, FALLS CHURCH, VA, 22040-0747, US

(21) Appl. No.: 10/157,853

(22) Filed: May 31, 2002

(30) Foreign Application Priority Data
Jun. 11, 2001 (KR) P2001-32474

(51) Int. Cl. H01L 21/4763

(52) U.S. Cl. 438/618

(57) ABSTRACT

A method for forming a metal line of a semiconductor device is disclosed, which improves a crystal structure of a Cu line 111 to improve electro-migration characteristics and reliability. The method includes forming a trench on a substrate by patterning an insulating interlayer. A barrier metal film is formed on the trench and the insulating interlayer. A seed Cu film is formed on the barrier metal film. A PVD metal film is formed on the seed Cu film by a physical vapor deposition (PVD) process. An electroplated metal film is deposited on the PVD metal film to fill the trench. Lastly, a metal line is formed in the trench by removing the films to expose the insulating interlayer on either side of the metal line in the trench.

### BACKGROUND OF THE INVENTION

1. Field of the Invention

The present invention relates to a semiconductor device. More particularly, the present invention relates to a method for forming a metal line, such as a copper (Cu) line, of a semiconductor device.

2. Background of the Related Art

A process for forming a Cu line on a semiconductor is known. For example, a Cu line can be formed on an IC circuit. At present, the process for forming the Cu line is based on an electroplating method.

Unlike a process for forming an Al line using a reactive ion etch (RIE) method, a Cu line is formed in such a manner that an insulating film pattern is formed using a dual damascene process. A barrier metal is then deposited. Next, a Cu electroplating is formed over the barrier metal.

At present, it is impossible to directly deposit Cu on the barrier metal using Cu electroplating. Therefore, Cu is first thinly deposited as a seed film. Then, a Cu electroplating is formed over the Cu seed film.

Unfortunately, it is impossible to uniformly deposit a Cu seed film by a physical vapor deposition (PVD). Specifically, when a fine inner portion of the insulating film pattern, having a fine size under a technology node of 0.13 μm or less, is desired, the process for forming a Cu line cannot be implemented by the electroplating method.

To overcome this drawback, research to form a Cu seed film using a Chemical Vapor Deposition (CVD) method, or a non-electroplating method, is now being implemented. In this case, the Cu line can be formed using a Cu electroplating method in a technology node less than 0.1 μm.

Unfortunately, the Cu film formed by a CVD method, or a non-electroplating method, has an irregular direction. Therefore, it is difficult to improve a crystal structure of a Cu line 111, when the Cu line is formed on the seed Cu film by an electroplating method. Poor crystal structure of the Cu line negatively influences Electro-Migration (EM) of the Cu line. Accordingly, there is a need in the art for a technique, which can improve the crystal structure of a Cu line 111.

A related art method for forming a metal line of a semiconductor device will be explained with reference to FIGS. 1A through 1C. An insulating interlayer 12 is formed on a silicon substrate 11 by a CVD process. Subsequently, a photoresist film (not shown) is deposited on the insulating interlayer 12, and then is patterned by exposure and developing processes. The insulating interlayer 12 is etched using the patterned photoresist film as a mask to form a trench, as illustrated in FIG. 1A. As a result, a region of the silicon substrate 11 is exposed.

Then, as shown in FIG. 1B, a barrier metal film 13 is formed on the surface of the insulating interlayer 12 and the trench by a PVD process. Next, a seed Cu film 14 is formed on the barrier metal film 13 by a CVD process, or a non-electroplating process. Afterwards, an electroplated Cu film 15 is formed on the entire surface by an electroplating method to fill the trench.

Then, as shown in FIG. 1C, the electroplated Cu film 15, the seed Cu film 14, and the barrier metal film 13 are planarized by a chemical mechanical polishing (CMP) process to expose the insulating interlayer 12. Thus, a multi-layered Cu line 16 is formed in the trench.

However, the related art method for forming a metal line of a semiconductor device suffers drawbacks. Since the Cu seed film 14, formed by a CVD method or a non-electroplating method, has an irregular direction, it is difficult to improve the crystal structure of the electroplated Cu film 111 when the electroplated Cu film is formed on the seed Cu film 14 by the electroplating method. This deteriorates EM characteristics, thereby decreasing a reliability of the Cu line.

### SUMMARY OF THE INVENTION

Accordingly, the present invention is directed to a method for forming a metal line of a semiconductor device that substantially obviates one or more of the drawbacks of the related art.

An object of the present invention is to provide a method for forming a metal line of a semiconductor device which improves a crystal structure of a Cu line 111.

Another object of the present invention is to provide a method for forming a metal line of a semiconductor device, which improves EM characteristics of a Cu line, thereby improving reliability of the Cu line.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for forming a metal line of a semiconductor device includes steps of forming a trench by patterning an insulating interlayer on a substrate; forming a barrier metal film on the trench and the insulating interlayer; forming a seed Cu film on the barrier metal film; forming a PVD metal film on the seed Cu film by a PVD process; depositing an electroplated metal film on the PVD metal film to fill the trench; and forming a metal line by exposing the insulating interlayer adjacent the metal line in the trench.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1C are cross sectional views illustrating a method for forming a metal line of a semiconductor device, according to the related art; and

FIGS. 2A to 2E are cross sectional views illustrating a method for forming a metal line of a semiconductor device, according to the present invention.

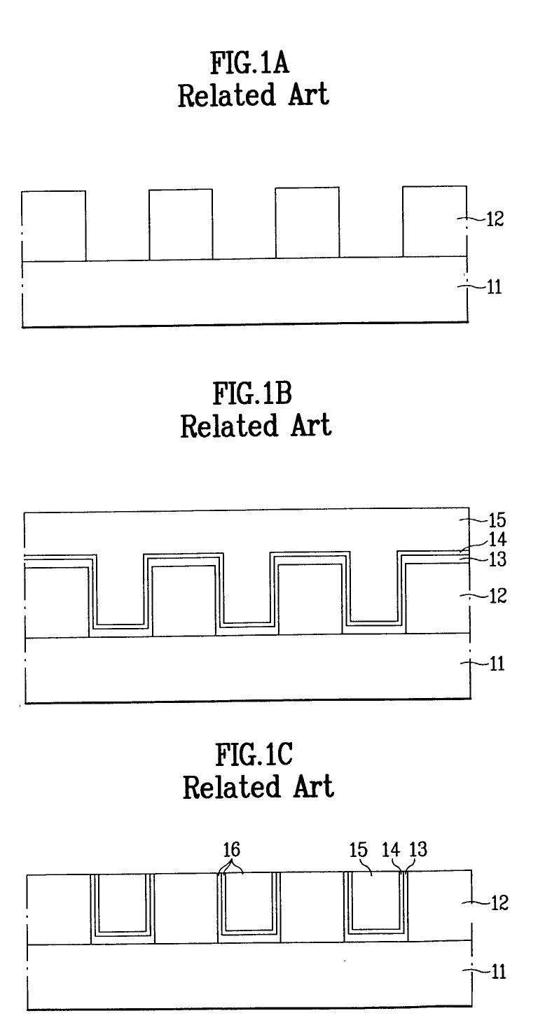

### DETAILED DESCRIPTION OF THE PREFERRED EMBODIMENT(S)

Reference will now be made in detail to the preferred embodiments of the present invention, examples of which are illustrated in the accompanying drawings.

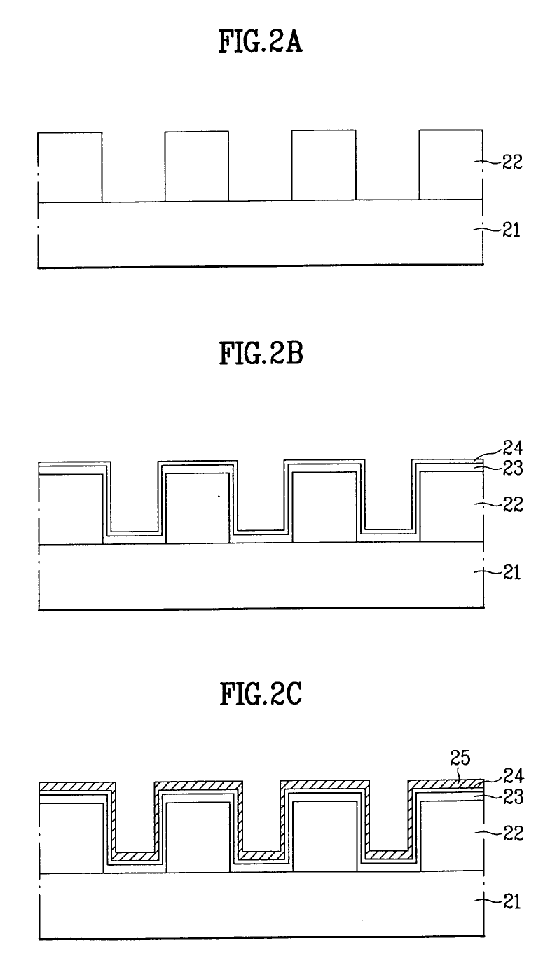

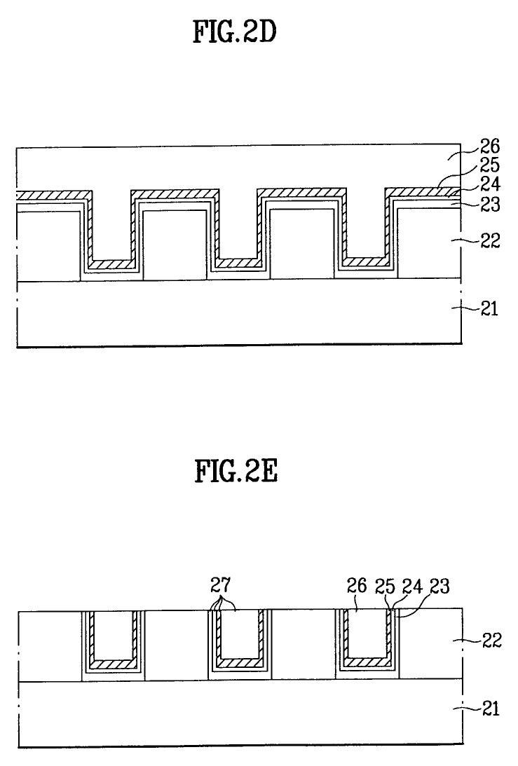

FIGS. 2A to 2E illustrate a method for forming a metal line of a semiconductor device, according to a preferred embodiment of the present invention. In the method, a silicon oxide film (SiO₂), or a low dielectric film (dielectric constant of about 1˜3), is deposited on a silicon substrate 21 by a CVD process to form an insulating interlayer 22.

Subsequently, a photoresist film is deposited on the insulating interlayer, and selectively patterned by exposure and developing processes. The insulating interlayer 22 is etched, using the patterned photoresist film as a mask, to form at least one trench, as illustrated in FIG. 2A. The trench may be formed by a single or dual damascene process, such that at least one region of the silicon substrate 21 is exposed.

Then, as shown in FIG. 2B, a barrier metal film 23 is formed on a surface of the insulating interlayer 22 and the trench by a PVD or CVD process. The barrier metal film 23 is formed by depositing Ta, TaN, TaC, WN, TiN, TiW, TiSiN, WBN, WC, or a similar substance. A seed Cu film 24 is then deposited on the barrier metal film 23 at a thickness of 10˜1000 Å, by a CVD or a non-electroplating process.

Subsequently, as shown in FIG. 2C, a PVD Cu film 25 is formed on the seed Cu film 24 at a thickness of 10˜1000 Å, by a PVD process. Afterwards, as shown in FIG. 2D, an electroplating method is used to fill the trench. For example, an electroplated Cu film 26 is deposited on the entire surface of the PVD Cu film 25.

As shown in FIG. 2E, an annealing process is performed within 24 hours after the electroplated Cu film 26 is formed. A single gas, such as N₂, Ar, or H₂, or a mixed gas, such as N₂+H₂, Ar+H₂, or Ar+N₂, is used during the annealing process.

The annealing process is performed in a RTP furnace or an oven furnace. In the RTP furnace, the annealing process would be performed for 1 sec to 20 min within the range of 250° to 500° C. In the oven furnace, the annealing process would be performed for 10 sec to 30 min within the range of 250° to 500° C. Subsequently, the electroplated Cu film 26, the PVD Cu film 25, the seed Cu film 24, and the barrier metal film 23 are planarized by a CMP process. Thereby, a multi-layered Cu line 27 is formed with the insulating interlayer 22 exposed on either side thereof.

In the above process, the seed Cu film 24, formed by a CVD or a non-electroplating method, has an irregular direction. However, the final electroplated Cu film 26 has a strong Cu crystal characteristic (111) after the annealing process. The final electroplated Cu film 26 has the strong Cu crystal characteristic because the PVD Cu film 25, deposited on the seed Cu film 24, has a strong Cu crystal characteristic (111).

Therefore, in the present invention, on a Cu film formed by a CVD or non-electroplating process, a Cu film is deposited again by a PVD process, and then a Cu electroplating process is performed. The method for forming a metal line of a semiconductor device according to the present invention has several advantages.

First, the electroplated Cu film 26 is formed after forming the PVD Cu film 25, having a good Cu crystal structure (111), on the seed Cu film 24. Therefore, the crystal structure (111) of the electroplated Cu film 26 is improved to form a reliable Cu line, which has a good electro-migration characteristic.

Second, the method of forming the Cu line is easy. Further, the Cu line can be formed small, so that the Cu line can be used as a technology node less than 0.1 μm.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method for fabricating a metal line of a semiconductor device comprising the steps of:
forming a trench by patterning an insulating interlayer on a substrate;
forming a barrier metal film on the trench and the insulating interlayer;
forming a seed Cu film on the barrier metal film;
forming a physical vapor deposition (PVD) metal film on the seed Cu film by a PVD process;
depositing an electroplated metal film on the PVD metal film to fill the trench; and
forming a metal line in the trench by exposing the insulating interlayer adjacent the trench.

2. The method as claimed in claim 1, wherein the PVD metal film, the electroplated metal film, and the metal line are formed of Cu.

3. The method as claimed in claim 1, wherein the insulating interlayer is formed of a silicon oxide film or a low dielectric film.

4. The method as claimed in claim 3, wherein insulating interlayer is formed of the low dielectric film, and the low dielectric film includes a material having a dielectric constant of approximately 1 to 3.

5. The method as claimed in claim 1, wherein the trench is formed by a single or dual damascene process.

6. The method as claimed in claim 1, wherein the barrier metal film is fabricated by either a chemical vapor deposition (CVD) process or a PVD process.

7. The method as claimed in claim 1, wherein the barrier metal film is formed of Ta, TaN, TaC, WN, TiN, TiW, TiSiN, WBN, or WC.

8. The method as claimed in claim 1, wherein the seed Cu film is formed by a CVD process or an electroless plating process.

9. The method as claimed in claim 1, wherein the seed Cu film has a thickness of approximately 10 to 1000 Å.

10. The method as claimed in claim 1, wherein the PVD metal film has a thickness of approximately 10 to 1000 Å.

11. The method as claimed in claim 1, further comprising the step of:
performing an annealing process after said step of depositing the electroplated metal film.

12. The method as claimed in claim 11, wherein the annealing process is performed using a single gas of N₂, Ar, or H₂.

13. The method as claimed in claim 11, wherein the annealing process is performed using a mixed gas of N₂+H₂, Ar+H₂, or Ar+N₂.

14. The method as claimed in claim 11, wherein the annealing process is performed using a rapid thermal process (RTP) furnace or an oven furnace.

15. The method as claimed in claim 14, wherein the annealing process is performed using the RTP furnace and is performed for approximately 1 seconds to 20 minutes within the range of approximately 250 to 500° C.

16. The method as claimed in claim 14, wherein the annealing process is performed in the oven furnace and is performed for approximately 10 seconds to 30 minutes within the range of approximately 250 to 500° C.

17. The method as claimed in claim 1, wherein said step of forming the metal line includes planarizing the electroplated metal film, the PVD metal film, and the seed Cu film with a chemical mechanical polishing (CMP) process.

18. The method as claimed in claim 2, wherein the insulating interlayer is formed of a silicon oxide film or a low dielectric film, and wherein the seed Cu film is formed by a CVD process or an electroless plating process.

19. The method as claimed in claim 18, further comprising the step of:
performing an annealing process after said step of depositing the electroplated metal film.

20. The method as claimed in claim 11, wherein the annealing process is performed within twenty-four hours after said step of depositing the electroplated metal film.
